(19) United States
(12) Patent Application Publication
(10) Pub. No.: US 2014/0073234 A1
(43) Pub. Date: Mar. 13, 2014

(54) CHASSIS WITH AN AIRFLOW ADJUSTMENT

(71) Applicants: Bret P. Elison, Rochester, MN (US); Phillip V. Mann, Rochester, MN (US); Arvind K. Sinha, Rochester, MN (US)

(72) Inventors: Bret P. Elison, Rochester, MN (US); Phillip V. Mann, Rochester, MN (US); Arvind K. Sinha, Rochester, MN (US)

(73) Assignee: INTERNATIONAL BUSINESS MACHINES CORPORATION, Armonk, NY (US)

(21) Appl. No.: 13/609,563

(22) Filed: Sep. 11, 2012

(51) Int. Cl. H05K 7/20; H05K 5/02

(52) U.S. Cl. 454/184; 361/695

(57) ABSTRACT

An apparatus and method is provided for conveying heat away from an electronic component. In one embodiment, an adjustable vane is positioned so that air in a channel is diverted from a first cooling zone to a second cooling zone by the adjustable vane to another part of the chassis using a control mechanism. The apparatus can be controlled in a way that regulates temperature of an electronic component by adjusting airflow within the chassis.

### TECHNICAL FIELD

Embodiments described herein generally relate to cooling, and more specifically, to cooling of electronic components in a chassis.

### BACKGROUND

Heat generated by electronic devices degrades many electronic devices within a chassis. These electronic devices need to be cooled in order to work effectively. In order to cool electronic devices, fresh, unheated air needs to be circulated over the components. The current dense placement of electronic devices and cooling devices in crowded electronic arrangements is a factor in providing for appropriate cooling within the chassis.

### SUMMARY

In an embodiment, a chassis is designed in an open configuration to include a first cooling zone, a second cooling zone, and a bypass zone. The chassis includes adjustable vanes and adjustable fans that are attached to the chassis and respond to parameters to provide for modified cooling flow in the second zone through use of the bypass zone.

### BRIEF DESCRIPTION OF THE DRAWINGS

Embodiments are illustrated by way of example, and not by way of limitation, in the figures of the accompanying drawings in which like reference numerals refer to similar elements or steps:

FIG. 1 shows a schematic representation of a retracted cooling system from the top view according to various embodiments.

FIG. 2 shows a schematic representation of an extended cooling system from the top view according to various embodiments.

### DETAILED DESCRIPTION

Heat may be removed from an electronic device and its immediate area in order for the device to maintain an operational temperature within desired limits. Failure to remove heat effectively results in increased device temperatures, which in turn, may lead to thermal runaway conditions causing decreased performance and potentially catastrophic failure. Thermal management is the process of maintaining a desirable temperature in electronic devices and their surroundings. As more devices are packed into a chassis, heat flux (Watts/cm2) increases, resulting in the need to more aggressively remove heat from a given electronic device. A common trend in the industry is to cool electronic devices using circulated air. However, cooling electronic devices in a crowded multi-electronic device environment may result in downstream warm air that may cool another electronic device. Noise limitations may prevent adding more fans downstream. Furthermore, fan reliability may be compromised by higher fan intake air temperature. Compounding the problem is that electronic devices require different cooling requirements with low power areas producing a lower heat flux and high power areas intermittently producing a higher heat flux. Due to space limitations from smaller form factors, separate ducts of air may also not be feasible. The need to cool current and future high heat load, variable heat flux electronic devices and systems therefore mandates the development of alternate cooling methods. An aspect of the current disclosure may be lower noise levels and a smaller form factor for modern electronic devices.

Features illustrated in the drawings are not necessarily drawn to scale. Descriptions of well-known components and processing techniques are omitted so as to not unnecessarily obscure the embodiments of the current disclosure. The examples used herein are intended merely to facilitate an understanding of ways in which the embodiments may be practiced and to further enable those of skill in the art to practice the current disclosure. It is also to be understood that the descriptions of the embodiments are provided by way of example only, and are not intended to limit the scope of this current disclosure as claimed.

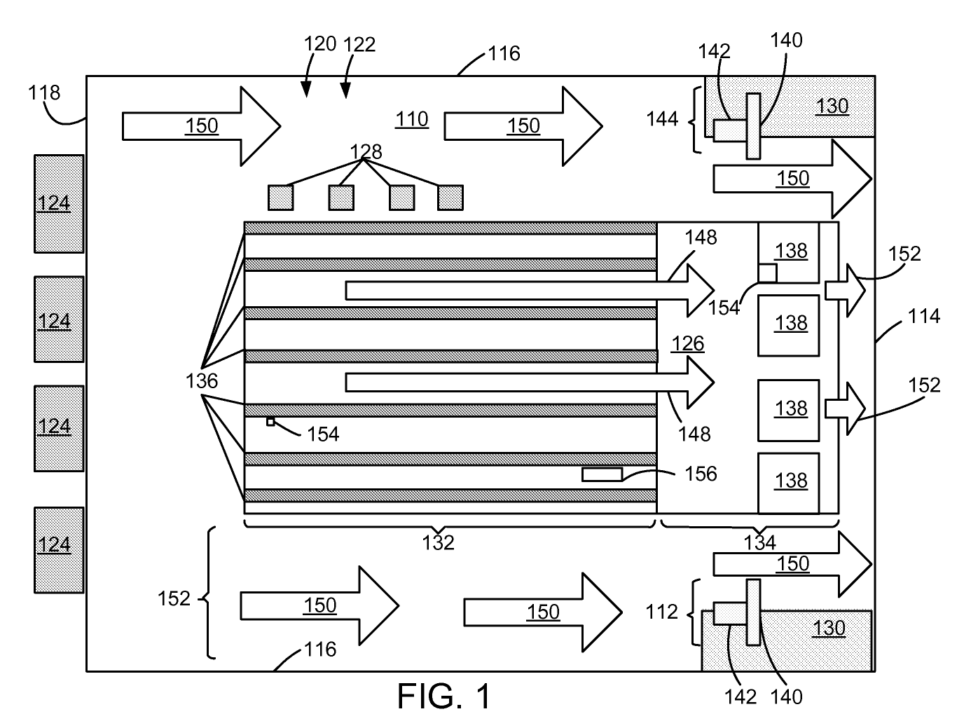

Shown in FIG. 1 is a chassis 110 in a ductless configuration according to an aspect of the current disclosure.

The chassis 110 has a front face 114, two sides 116, a rear face 118, a top 120, and a bottom 122. The chassis 110 may be of sufficient size to fit into a 19-inch server rack. The chassis 110 may be made of materials to facilitate cooling such as copper, sheet metal, plastic, or wood. In the embodiment shown, the rear face 118 and front face 114 may be made of perforated sheet metal and the sides 116, top 120, and bottom 122 may be made of solid sheet metal.

There is at least one fan 124 which may be located generally near and parallel to the rear face 118. The fan 124 may be attached external to the rear face 118, but the fan 124 may be attached internal to the rear face 118 or mounted in another appropriate fashion. The fan 124 may be oriented so that air flows into the chassis 110. The fans 124 may be counter rotating in pairs. In FIG. 1, two fans 124 may be counter-rotating.

The chassis 110 contains at least one circuit board 126 attached to the bottom 122, but other configurations are contemplated. In FIG. 1, for example, fiber optic ports 128 are attached to the bottom 122 and two power supplies 130 may be located along the side 116 within the chassis 110, but other configurations are contemplated.

The chassis 110 contains a first cooling zone 132 and a second cooling zone 134. In the first cooling zone 132, there is at least one first electronic component 136. The first electronic component 136 may be comprised of memory units or other generally consistent heat flux devices. In the shown embodiment, for purposes of illustration and not limitation, there are seven memory units 136 attached to the circuit board 126 arranged generally perpendicularly to the rear face 118 and perpendicularly to the bottom 122. The memory units 136 may be parallel to other memory units 136 with adequate spacing between each memory unit 136, but other configurations are contemplated. In the shown embodiment, the memory units 136 may be dual in-line memory modules (DIMMs), single in-line memory modules (SIMMs), hard drives, Solid State Drives (SSDs), or other consistent heat flux devices and may be used with heat sinks.

In the second cooling zone, there may be at least one second electronic component 138. The second electronic component 138 may be comprised of processors or other generally variable heat flux electronic devices. The second electronic component 138 is, for purposes of illustration and not limitation, comprised of four processors arranged in a linear fashion, mounted on the circuit board 126, and generally parallel with the front face 114, with adequate spacing between each processor 138. In the shown embodiment, the processors 138 may be CPUs but the processors can also be GPUs or wireless transmitters or similar electronic components.

Vanes 140 may be provided to redirect the airflow within the chassis. The chassis may contain at least one vane motor 142 and at least one vane 140. A vane is any device that redirects airflow, such as baffles, louvers, dampers, or any other similar device. In the embodiment of FIG. 1, two vane motors 142 are, for purposes of illustration, shown as not activated, and the two vanes 140 are retracted into slots 144 so that airflow is not impeded or redirected, but other embodiments that do not impede airflow are permitted For example, other embodiments may include vanes in flush alignment with the chassis parallel to the airflow or retracted into the power supply. The vane motor 142 may be an actuator, a stepper motor, a spring mechanism, or other similar mechanisms suitable for actuating the vane mechanism.

The vanes 140 may be made of any material that allows for deflection of the airflow such as plastic, fiberglass, glass, sheet metal, carbon fiber, or perforated metal. In the shown embodiment, the vanes 140 are made of sheet metal. The vanes 140 are of a sufficient height and length to deflect airflow. In the present embodiment, the vanes are 5U in height, a unit known in the art, and shorter than the distance from the base of the vane 140 to the processor.

The vane motor 142 and vanes 140 may be positioned in order to route air. In the shown embodiment, the vanes 140 are attached to the power supply 130 perpendicularly to the airflow and perpendicular to the bottom 122, but other angles and locations that maximize airflow may be permitted. The vane motor 142 and vanes 140 may be attached with a number of attachment techniques, including, for example, but not limited to adhesive or welding.

To cool the electronic components in the chassis, air may move into the chassis 110 to create an airflow. In the shown embodiment, the airflow is created by the fan 124, but the airflow may be created by an external cooling device such as a building HVAC system or a room fan. Within the chassis 110, the airflow may be separated into separate airflows, such as for example, a low velocity airflow 148 and a high velocity airflow 150. Low velocity 148 and high velocity airflow 150 are relative to each other. The low velocity airflow 148 may be impeded by the first electronic device 136, thus slowing the airflow relative to the high velocity airflow 150, which may have a travel path with little impedance.

The low velocity airflow 148 may pass through the circuit board 126. While the low velocity airflow 148 passes through the circuit board 126, heat from the first cooling zone may be removed. In the shown embodiment, the low velocity airflow 148 flows parallel to the memory units 136. The low velocity airflow 148 may be warmed by heat from the first cooling zone 132 before passing through the second cooling zone 134. After passing through the second cooling zone 134, the airflow may be heated further 152 and may exit the chassis 110 through the front face.

The high velocity airflow 150 moves at a higher speed along the side of the chassis 110 with minimal heat flux transfer. The high velocity airflow 150 may form the bypass zone 152, which is the area between the side 116 and the circuit board 126. The high velocity airflow 150 may pass over the vane 140 and power supply 130 with minimal air impedance and may exit out of the front face of the chassis 114.

The chassis may contain at least one sensor 154. The sensor 154 may monitor a parameter. The parameter may be a temperature indication or other indication sufficient to determine the need for further cooling in the second cooling zone 134. The parameter may also be ambient temperature, airflow, airflow temperature, processor 138 temperature, processor 138 clock speed, processor 138 current draw, or processor 138 voltage. The shown embodiment has two sensors, one sensor 154 on the processor 138 to monitor processor clock speed and another sensor 154 on the memory unit 136 to monitor airflow temperature. The sensors 154 may be mounted on multiple locations in the area of the chassis 110 sufficient to generate cooling data. The sensor 154 may transmit data on the parameter to the control mechanism 156.

The chassis may contain at least one control mechanism 156. The control mechanism may make adjustments to the airflow based on parameter data from the sensors. The control mechanism may further adjust the vanes 140 or the fan 134. The control mechanism 126 may be mounted in any location on the chassis. In the shown embodiment, one control mechanism 156 is mounted on the circuit board 126 but other configurations are contemplated.

In the shown embodiment, the processor 138 may be in a low power state. The sensor may transmit the lower temperature data to the control mechanism 156, and the control mechanism 156 may compare the processor clock speed to a predetermined higher threshold to determine if more airflow is needed. In the shown embodiment, the processor 138 clock speed is lower than the predetermined higher threshold and there is no action by the control mechanism 156 and the vane 140 may remain in a retracted configuration. In the retracted vane 140 configuration, the airflow 150 may bypass the second cooling zone 134. This may be necessary when the processor 138 is under low computational strain because lower computations from the processor 138 result in lower heat output. Therefore, the fan noise will not increase beyond, for example, 7.1 bels, which is a Declared A-Weighted Sound Power Level known by those with skill in the art. In other embodiments, other appropriate noise limits may be set with respect to controlling fan noise during cooling operation.

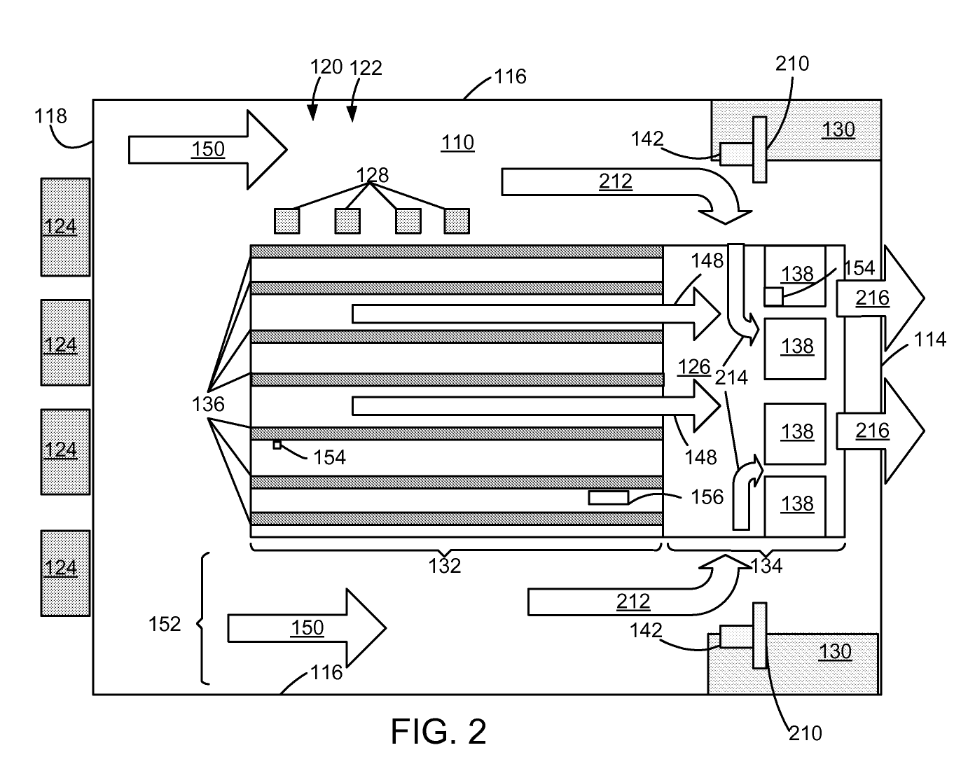

The extended vane 210 is shown in FIG. 2, which depicts a top view of the same chassis 110 in FIG. 1. The control mechanism 156 may extend the vane 210 and increase fan 124 output in response to a higher parameter reading from the sensor 154. When the temperature indication, or other parameter, from the sensor 154 is above a particular parameter threshold, the control mechanism may, in any combination, activate the vane motor 142 to extend the vane 210 in order to redirect airflow to the second cooling zone 134 and increase fan 124 output to increase airflow. In the shown embodiment, the extended vane 210 may be triggered when the sensor 154 transmits processor 138 clock data to the control mechanism 156 and the control mechanism 156 compares a processor clock speed that is higher than the predetermined high threshold. As a response, the control mechanism 156 may control the position of the vane 140 through a vane motor 142 and the fan 124 output by RPM or blade pitch.

The control mechanism 156 may also, in any combination, reverse the vane motor 142 to retract the vane 210 and decrease fan 124 output. The control mechanism 156 may go back to the retracted position 140 in FIG. 1 in response to a lower parameter reading. For example, the sensor 154 may transmit clock data to the control mechanism 156 and the control mechanism 156 may compare a processor clock speed that is lower than the predetermined low threshold and decide that enough cooling to the second cooling zone 134 has occurred. The control mechanism 156 may retract vanes 215 and decrease fan 124 output.

In the extended vane configuration 210, the vane motor 142 activates and extends the vane 210. The extended vane 210 may have sufficient height and length to route air from the bypass zone 152 to the second cooling zone 134. The extended vane 210 may also have sufficient stiffness and locking capability such that the extended vane does not move in response to airflow 212.

The extended vane may reroute the bypassed airflow 212 towards the second cooling zone 134 and may form a routed airflow 214. This routed airflow 214 is pushed forward by the high resistance airflow 148 and absorbs heat from the second cooling zone 134 and vents airflow 216 outside of the chassis. In the shown embodiment, the airflow 216 is vented through the front but other configurations are contemplated such as through the side or top.

While the disclosed subject matter has been described with reference to illustrative embodiments, this description is not intended to be construed in a limiting sense. Various modifications of the illustrative embodiments, as well as other embodiments of the subject matter, which are apparent to persons skilled in the art to which the disclosed subject matter pertains are deemed to lie within the scope and spirit of the disclosed subject matter.

What is claimed is:

1. A method, comprising the steps of:
creating an airflow in a chassis, wherein the chassis includes a first cooling zone with a first electronic component, a second cooling zone with a second electronic component located downstream of the first cooling zone, and a bypass zone which allows a portion of the airflow to bypass the first and second cooling zones; and
modifying the airflow from the bypass zone into the second cooling zone.

2. The method of claim 1, wherein modifying the airflow from the bypass zone into the second cooling zone includes:
adjusting a vane to regulate airflow to the second cooling zone; and
regulating the airflow into the chassis.

3. The method of claim 1, wherein modifying the airflow from the bypass zone into the second cooling zone is a response to one or more parameters.

4. The method of claim 2, wherein regulating airflow into the chassis includes adjusting the airflow output of a fan.

5. The method of claim 3, wherein the one or more parameters includes an operating temperature of one or more components within the second cooling zone.

6. The method of claim 3, wherein the one or more parameters includes monitoring a clock speed of a processor.

7. A chassis, comprising:
an airflow, wherein a first cooling zone with a first electronic component is formed upstream from a second cooling zone with a second electronic component, and a bypass zone is formed outside of the first cooling zone and the second cooling zone;
a sensor, wherein the sensor monitors one or more parameters;
a control mechanism, wherein the control mechanism controls a temperature in the chassis;
an adjustable vane, wherein the adjustable vane responds to the control mechanism to adjust the airflow with respect to the first and second cooling zones using the bypass zone.

8. The chassis in claim 7, wherein the chassis has a front and a back comprised of a material that enhances airflow to a circuit board and the airflow occurs in an open configuration.

9. The chassis in claim 7, wherein the one or more parameters is at least a temperature indication.

10. The chassis in claim 7, wherein the airflow is created by an adjustable airflow fan.

11. The chassis in claim 7, wherein the first electronic component is a DIMM and the second electronic component with a variable heat flux is a processor.

12. The chassis in claim 9, wherein the temperature indication is at least a second cooling zone temperature.

13. The chassis in claim 9, wherein the temperature indication is a processor's calculations per second.

14. A chassis, comprising:
an airflow, wherein a first cooling zone with a first electronic component is formed upstream from a second cooling zone with a second electronic component, and a bypass zone is formed outside of the first cooling zone and the second cooling zone;
a vane, wherein the vane adjusts the airflow to an electronic component; and
a control mechanism, wherein a sensor senses a parameter and the control mechanism determines exceeds a threshold and adjusts airflow to modify the parameter.

15. The chassis in claim 14, wherein the first electronic component includes a consistent heat flux electronic component.

16. The chassis in claim 14, wherein the second electronic component includes a variable heat flux electronic component.

17. The chassis in claim 14, wherein the vane further comprises:
a vane motor; and
a retaining mechanism, wherein the vane remains in a fixed position.

18. The chassis in claim 14, wherein the parameter is at least a temperature of the airflow.

19. The chassis in claim 15, wherein the consistent heat flux electronic component is a DIMM.

20. The chassis in claim 17, wherein the vane is positioned so that airflow is diverted to the second cooling zone.
